(19) United States
(12) Patent Application Publication
(10) Pub. No.: US 2025/0271506 A1
(43) Pub. Date: Aug. 28, 2025

(54) INFORMATION PROCESSING DEVICE, BATTERY SYSTEM, STORAGE MEDIUM, AND INFORMATION PROCESSING METHOD

(71) Applicant: KABUSHIKI KAISHA TOSHIBA, Tokyo (JP)

(72) Inventors: Yohei UEMURA, Koganei Tokyo (JP); Wen ZHANG, Sagamihara Kanagawa (JP); Sayaka MORIMOTO, Kawasaki Kanagawa (JP); Ryosuke YAGI, Yokohama Kanagawa (JP)

(73) Assignee: KABUSHIKI KAISHA TOSHIBA, Tokyo (JP)

(21) Appl. No.: 19/051,280

(22) Filed: Feb. 12, 2025

(30) Foreign Application Priority Data
Feb. 28, 2024 (JP) 2024-028075

(51) Int. Cl. G01R 31/392; G01R 31/385; G01R 31/396; G08B 21/18; H01M 10/48

(52) U.S. Cl. CPC G01R 31/392; G01R 31/385; G01R 31/396; G08B 21/182; H01M 10/486

(57) ABSTRACT

According to an embodiment, an information processing device includes a processing circuit configured to: obtain a first evaluation index of a plurality of unit cells in a battery module, and obtain a second evaluation index in a case where a first unit cell in the battery module and a second unit cell in the battery module are swapped on a basis of the first evaluation index, wherein the first evaluation index and the second evaluation index are obtained on a basis of a positive electrode potential and a temperature rise rate.

### CROSS-REFERENCE TO RELATED APPLICATION

This application is based upon and claims the benefit of priority from Japanese Patent Application No. 2024-028075, filed Feb. 28, 2024, the entire contents of which are incorporated herein by reference.

### FIELD

Embodiments of the present invention relate generally to an information processing device, a battery system, a non-transitory storage medium, and an information processing method.

### BACKGROUND

When a unit cell is used as a battery module, individual degradation rates vary depending on the installation position and the like of the unit cell, and the life of the battery module may be shortened.

### DESCRIPTION OF THE DRAWINGS

FIG. 1 is a block diagram illustrating a schematic example of a battery system according to an embodiment;

FIG. 2 is a flowchart illustrating an example of a battery diagnosis method according to an embodiment;

FIG. 3 is a block diagram illustrating a schematic modification of the battery system according to the embodiment;

FIG. 4 is a flowchart illustrating a modification of the battery diagnosis method according to the embodiment;

FIG. 5 is a block diagram illustrating a schematic modification of the battery system according to the embodiment; and

FIG. 6 is a flowchart illustrating a modification of the battery diagnosis method according to the embodiment.

### DETAILED DESCRIPTION

According to an embodiment, an information processing device includes a processing circuit configured to: obtain a first evaluation index of a plurality of unit cells in a battery module; and obtain a second evaluation index in a case where a first unit cell in the battery module and a second unit cell in the battery module are swapped on a basis of the first evaluation index, in which the first evaluation index and the second evaluation index are obtained on a basis of a positive electrode potential and a temperature rise rate.

Hereinafter, embodiments will be described with reference to the drawings. In the following description, components that exhibit the same or similar functions are denoted by the same reference numerals throughout all the drawings, and redundant description will be omitted. In addition, each drawing is a schematic view for facilitating the description of the embodiment and the understanding thereof, and the shape, size, ratios, and the like are different from those of the actual device, and these can be appropriately modified in design in consideration of the following description and known techniques.

The battery module is formed of a unit cell of two or more secondary batteries. The secondary battery will be described below as a lithium ion secondary battery. The unit cell includes a positive electrode and a negative electrode as electrodes, and the positive electrode and the negative electrode are opposite in polarity to each other. In each of the positive electrode and the negative electrode of the unit cell, the potential changes according to the change in the state of charge. In each of the positive electrode and the negative electrode, there is a predetermined relationship between the potential and the state of charge. Therefore, for each of the electrodes of the secondary battery, the potential can be calculated based on the charge state, and the charge state can be calculated based on the potential.

The information processing device according to the present embodiment uses an evaluation index to evaluate a degradation state of each unit cell in the battery module. The evaluation index is a numerical value of the possibility of occurrence of an event that hinders normal operation, such as degradation of a unit cell or occurrence of a rapid temperature rise due to progress of degradation. When the positive electrode potential of the unit cell is high, chemical reactions such as structural change and decomposition of the positive electrode active material are likely to occur, and desorption of lithium ions and metal deposition are promoted. In addition, when the temperature of the unit cell rises, those degradation reactions become faster. Therefore, in the present invention, the positive electrode potential and the temperature rise rate of a unit cell are employed as evaluation indices.

### First Embodiment

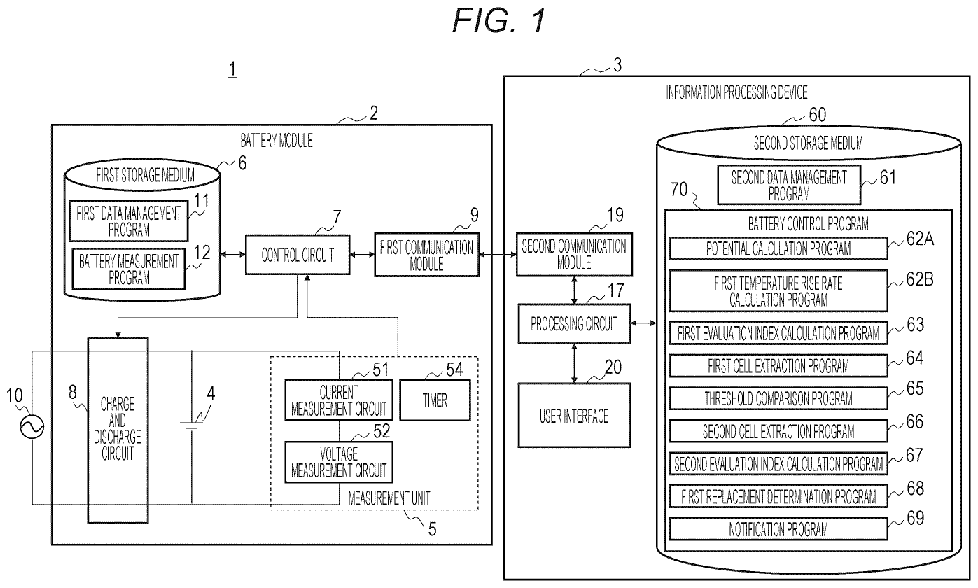

FIG. 1 is a block diagram illustrating a schematic example of a battery system according to an embodiment. In the embodiment, the battery system 1 includes an information processing device 3 and a unit cell 4 (first unit cell). The unit cell 4 is included in the battery module 2. In addition to the unit cell 4, the battery module 2 includes a measurement unit 5, a first storage medium 6, a control circuit 7, a charge and discharge circuit 8, and a first communication module 9. The measurement unit 5 includes a current measurement circuit 51 of the unit cell 4, a voltage measurement circuit 52 for measuring a voltage, and a timer 54. The measurement unit 5 may further include a temperature sensor. The first storage medium 6 includes a first data management program 11 capable of managing data entry and exit, and a battery measurement program 12 for measuring a state of charge (SOC) and a voltage of the unit cell 4. The information processing device 3 includes a second storage medium 60, a processing circuit 17, and a second communication module 19. The information processing device 3 may further include a user interface 20. The second storage medium 60 stores a second data management program 61 capable of managing entrance and exit of data and a battery control program 70 capable of controlling the unit cell 4.

The battery control program 70 includes: a potential calculation program 62A that calculates a positive electrode potential of a unit cell 4; a first temperature rise rate calculation program 62B that calculates a temperature rise rate of the unit cell 4; a first evaluation index derivation program 63 that derives a first evaluation index of all the unit cells; a first cell extraction program 64 that extracts a unit cell having a largest evaluation index; a threshold comparison program 65 that compares the evaluation index of the extracted unit cell with a threshold; a second cell extraction program 66 that extracts a unit cell having a smallest evaluation index; a second evaluation index derivation program 67 that derives an evaluation index when the unit cell extracted by the first cell extraction program 64 and the unit cell extracted by the second cell extraction program 66 are virtually swapped; and a first replacement determination program 68 that compares the evaluation index derived by the second evaluation index derivation program 67 with the threshold. The battery control program 70 may further include a notification program 69 for notifying swapping of a unit cell or replacement with a new unit cell. The program included in the battery control program 70 is not necessarily stored in the second storage medium 60. For example, the program only needs to be able to receive an instruction for executing the program issued from the processing circuit 17 and execute the program. Therefore, the programs may be stored in different storage media or may be operated in a cloud.

Examples of the battery module 2 include a large power storage device for a power system, a smartphone, a vehicle, a stationary power supply device, a robot, a drone, and the like. Examples of the vehicle to be the battery module 2 include a railway vehicle, an electric bus, an electric car, a plug-in hybrid car, and an electric motorcycle. Any device may be used as long as the device uses a secondary battery.

The measurement unit 5 can detect and measure parameters related to the unit cell 4 at a plurality of measurement time points in a state where the unit cell 4 is charged or discharged.

The current measurement circuit 51 acquires a current value of the unit cell 4.

The voltage measurement circuit 52 acquires a voltage value of the unit cell 4.

The timer 54 can measure the time when the parameter related to the unit cell 4 is measured.

The first storage medium 6 is a storage device called a main storage device or an auxiliary storage device. Examples of the first storage medium 6 include a magnetic disk, an optical disc (CD-ROM, CD-R, DVD, or the like), a magneto-optical disk (MO or the like), and a semiconductor memory. The battery module 2 may include only one memory or a plurality of memories serving as first storage medium 6. The first storage medium 6 stores a program executed by the control circuit 7, data of a result of executing the program, and data such as a measurement result of the measurement unit 5.

The control circuit 7 includes a processor, an integrated circuit, or the like, and the processor or the like constituting the control circuit 7 includes any of a central processing unit (CPU), an application specific integrated circuit (ASIC), a microcontroller unit (microcomputer), a field programmable gate array (FPGA), a digital signal processor (DSP), and the like. The control circuit 7 may include one processor or the like, or may include a plurality of processors or the like. The control circuit 7 reads and executes the program stored in the first storage medium 6, and controls charging and discharging of the unit cell 4 via the charge and discharge circuit 8. For example, the control circuit 7 switches between a state in which the unit cell 4 is charged and a state in which the unit cell 4 is discharged by switching the state of the charge and discharge circuit 8. In addition, in a state where the unit cell 4 is charged, the control circuit 7 controls the drive of the power supply 10 that supplies power to the unit cell 4 and the drive of the charge and discharge circuit 8, thereby adjusting the magnitude of the current input to the unit cell 4 and the like.

The control circuit 7 reads and executes the battery measurement program 12 from the first storage medium 6, and measures the SOC of the unit cell 4. The control circuit 7 can acquire measurement results of parameters related to the unit cell 4 including data related to the current value and the voltage value of the unit cell 4 from the measurement unit 5, and input measurement data including these measurement results and data related to the calculated SOC to the first storage medium 6. The control circuit 7 can also transmit data obtained by the battery measurement program 12 to the information processing device 3 via the first communication module 9. The measurement data includes a measurement value, a change amount (time history), and the like at each of a plurality of measurement time points. Further, the measurement data may include a change amount (time history) of the current of the unit cell 4, a change amount (time history) of the voltage of the unit cell 4, and a change amount (time history) of the temperature of the unit cell 4. Then, the processing circuit 17 of the information processing device 3 receives the data transmitted from the battery module 2 via the second communication module 19.

In the battery module 2, a battery management unit (BMU) is configured by the control circuit 7, the first storage medium 6, and the like.

For example, an AC/DC converter, a transformer circuit, and the like are mounted on the charge and discharge circuit 8. Then, in the charge and discharge circuit 8, AC power from the power supply 10 is converted into DC power by an AC/DC converter or the like, and a voltage of power supplied from the power supply 10 is transformed into a voltage corresponding to the unit cell 4 by a transformation circuit or the like. As a result, DC power is supplied to the unit cell 4 at a voltage corresponding to the unit cell 4, and a charging current is input to the unit cell 4.

The first communication module 9 includes a communication interface of the battery module 2 and the like. The control circuit 7 can communicate with a processing device outside the battery module 2 including the information processing device 3 via the first communication module 9.

The information processing device 3 is a processing device (computer) such as a server provided outside the battery module 2, and communicates with the first communication module 9 of the battery module 2 via the second communication module 19.

The second storage medium 60 included in the information processing device 3 is a storage device called a main storage device or an auxiliary storage device. For example, the information processing device 3 may be provided with only one storage device serving as the second storage medium 60, or may be provided with a plurality of storage devices.

The processing circuit 17 included in the information processing device 3 includes a processor, an integrated circuit, or the like, and includes any of a CPU, an ASIC, a microcomputer, an FPGA, a DSP, and the like as a processor constituting the processing circuit 17. The processing circuit 17 may include one processor or the like, or may include a plurality of processors or the like. The processing circuit 17 performs processing by executing a program or the like stored in the second storage medium 60. In the example of FIG. 1, the processing circuit 17 executes the second data management program 61 to write data to the second storage medium 60 and read data from the second storage medium 60. The processing circuit 17 executes the battery control program 70 to perform processing described below in the control of the unit cell 4.

The second communication module 19 includes a communication interface and the like of the processing device constituting the information processing device 3. The processing circuit 17 communicates with a device or the like outside the information processing device 3 including the battery module 2 via the second communication module 19.

The user interface 20 can output information related to information processing of the unit cell 4 and input related to information processing of the unit cell 4 by a user or the like of the information processing device 3 and the battery system 1. Therefore, the user interface 20 is provided with an output device that outputs information related to information processing of the unit cell 4. The output device outputs information to the outside by screen display, sound transmission, vibration, or the like. Note that the output device can output information related to information processing of the battery to the user in response to an instruction from the processing circuit 17. In addition, the user interface 20 is provided with an input device to which the user inputs an operation. The input device includes, for example, any one or more of a button, a mouse, a touch panel, a keyboard, a voice input device, and the like. Note that the user interface 20 may be provided separately from the processing device constituting the information processing device 3.

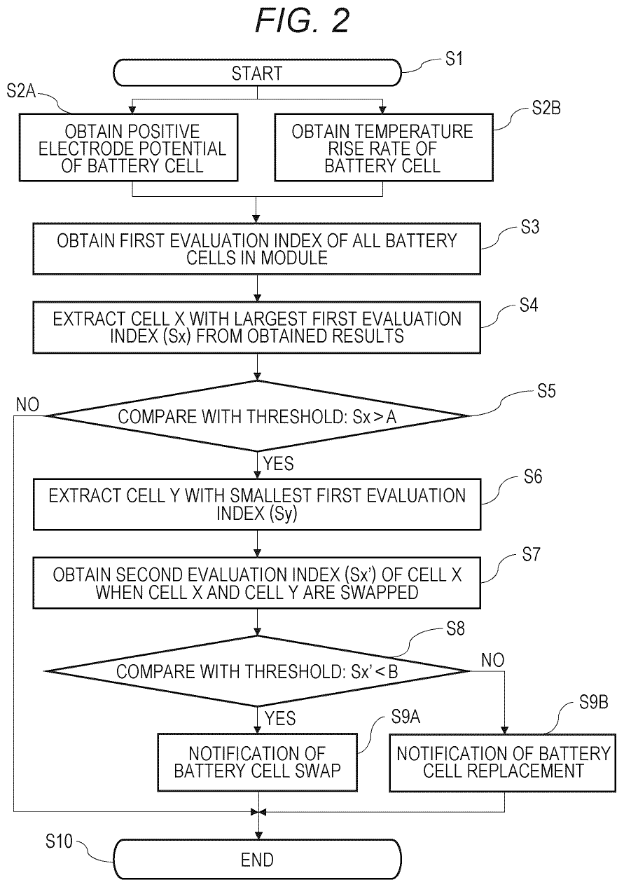

A flow of a battery diagnosis method according to an embodiment will be described. FIG. 2 is a flowchart illustrating an example of a flow of the battery system according to the embodiment. Note that this flowchart is an example, and the order of processing and the like are not limited as long as a required processing result can be obtained. Each processing result may be sequentially stored in the second storage medium 60, and each step may acquire the processing result with reference to the second storage medium 60. The same applies to the subsequent flowcharts.

In S2A, the processing circuit 17 reads and executes the potential calculation program 62A to calculate the positive electrode potential of the unit cell 4. The positive electrode potential can be calculated, for example, by creating and analyzing a charge and discharge curve using a voltage and an SOC.

In S2B, the processing circuit 17 reads and executes the first temperature rise rate calculation program 62B to calculate the temperature rise rate of the unit cell 4. The temperature rise rate can be calculated, for example, from the distance from the surface of the unit cell 4 to the surface of the battery module 2 and a thermal conductivity in the battery module 2. Specifically, the distance from the surface of each unit cell 4 to the surface of the battery module 2 is calculated in advance. The thermal conductivity can be calculated according to the material used for the unit cell 4 or the battery module 2. The temperature rise rate increases, for example, as the distance from the surface increases and as the thermal conductivity decreases. The information on the temperature acquired in S2B is determined by the arrangement of the unit cells 4 in the battery module 2, and thus does not depend on the performance of each unit cell 4.

In S3, the processing circuit 17 reads and executes the first evaluation index derivation program 63 to derive the first evaluation index in all the unit cells 4 in the battery module 2 from the positive electrode potential and the temperature rise rate.

The first evaluation index and the second evaluation index will be described. Hereinafter, the first evaluation index and the second evaluation index may be collectively referred to as an evaluation index. The evaluation index is an index obtained based on the positive electrode potential of a unit cell and the temperature rise rate. The evaluation index can be defined as, for example, a numerical value that increases as the positive electrode potential increases or as the temperature rise rate of the unit cell increases. The evaluation index may be a numerical value that decreases as the positive electrode potential of the unit cell is higher or as the temperature rise rate of the unit cell is higher. Both the first evaluation index and the second evaluation index are values derived using the positive electrode potential and the temperature rise rate in the unit cell in the battery module, but the second evaluation index is a value in a case where the unit cells are virtually swapped with each other. The temperature rise rate does not depend on the unit cell but depends on the position in the battery module. Therefore, as the temperature rise rate used in deriving the second evaluation index, the temperature rise rate of the unit cell at the assumed position to be swapped is adopted. For example, when the cell P and the cell Q are swapped, the value of the positive electrode potential of the cell P and the temperature rise rate of the cell Q are used as the second evaluation index of the cell P.

The positive electrode potential of the unit cell is denoted by vᵢⱼ, the temperature rise rate of the unit cell is denoted by tᵢⱼ, and the first evaluation index is denoted by Sᵢⱼ. Table 1 shows various numerical values in a unit cell in the battery module 2 in calculating the first evaluation index.

In Table 1, there are eight frames in a vertical direction i and three frames in a horizontal direction j, for a total of 24 frames. This table is regarded as a battery module, and each frame is regarded as a unit cell. In other words, eight unit cells are arranged in the vertical direction i and three unit cells are arranged in the horizontal direction j, and one battery module is formed by 24 unit cells. The value in each frame represents a positive electrode potential in (a) of Table 1, a temperature rise rate of a unit cell in (b) of Table 1, and a first evaluation index calculated using a function described below in (c) of Table 1. The first evaluation index represents a value obtained by multiplying the obtained value by 100.

In general, the higher the positive electrode potential of a unit cell or the higher the temperature rise rate, the more the unit cell is degraded. Therefore, in order to express the evaluation index, it is desirable to express the evaluation index using an expression capable of reflecting the actual degradation state of the unit cell in detail, and for example, the evaluation index can be expressed using a function. The first evaluation index Sᵢⱼ is expressed as the following Equation using the evaluation function Fᵥ of the positive electrode potential and the evaluation function Fₜ of the temperature rise rate of the unit cell:

$${S}_{i , j} = {F}_{v} ( {v}_{i , j} ) \times \{ 1 + {C}_{t} \times {F}_{t} ( {t}_{i , j} ) \} \qquad [ formula 1 ]$$

vᵢⱼ represents the positive electrode potential of the unit cell, tᵢⱼ represents the temperature rise rate of the unit cell, and Cₜ represents the weighting of the unit cell temperature (any positive number). A set of [i, j] represents a position of a unit cell in the battery module, and in a case where the number of unit cell arrangements is 8×3, i takes a value of 1 or more and 8 or less, and j takes a value of 1 or more and 3 or less. Here, Fᵥ is represented as the following Equation:

$${F}_{v} ( {v}_{i , j} ) = \frac{{v}_{i , j} - {v}_{min}}{{v}_{min}} \qquad [ formula 2 ]$$

vₘᵢₙ is a positive electrode potential of an unused unit cell, and is, for example, 4.17. In addition, Fₜ is expressed as the following Equation:

$${F}_{t} ( {t}_{i , j} ) = \frac{{t}_{i , j} - {t}_{min}}{{t}_{min}} \qquad [ formula 3 ]$$

tₘᵢₙ is a minimum temperature rise rate in a unit cell in the battery module 2.

In Table 1, a first evaluation index when [i, j] is, for example, [3, 2] is considered. When Cₜ=1.0, the first evaluation index Sᵢⱼ can be obtained as follows:

$${S}_{3 , 2} = {F}_{v} ( {v}_{3 , 2} ) \times \{ 1 + {C}_{t} \times {F}_{t} ( {t}_{3 , 2} ) \} = \frac{4.28 - 4.17}{4.17} \times \{ 1 + 1. 0 \times \frac{0.77 - 0.50}{0.5} \} = 0.0406 \qquad [ formula 4 ]$$

The definitions of the evaluation function of the positive electrode potential and the evaluation function of the temperature rise rate are not limited to those shown here. In calculating the evaluation index, elements other than the positive electrode potential and the temperature rise rate can also be added. For example, a probability dᵢⱼ of deformation due to impact may be added to Equation 2 as follows:

$${S}_{i , j} = {F}_{v} ( {v}_{i , j} ) \times \{ 1 + {C}_{t} \times {F}_{t} ( {t}_{i , j} ) \} \times \{ 1 + {C}_{d} \times {F}_{d} ( {d}_{i , j} ) \} \qquad [ formula 5 ]$$

Here, F_{d} is an evaluation function of the deformation probability, and C_{d} is weighting of the deformation probability (arbitrary positive number).

In S4, the processing circuit 17 reads and executes the first cell extraction program 64 to extract a unit cell (first unit cell) having the largest first evaluation index from the result calculated in S3. This is defined as a cell X, and the first evaluation index of the cell X is defined as Sₓ.

The evaluation index can also be obtained based on the correspondence relationship of the evaluation index with respect to the positive electrode potential of the unit cell and the temperature rise rate. As an example of the correspondence relationship, a tabular form can be adopted.

In the tabular form, for example, an item of the positive electrode potential is provided on the vertical axis, an item of the temperature rise rate is provided on the horizontal axis, and a predetermined evaluation index is set at a place where a certain value of the positive electrode potential and a certain value of the temperature rise rate intersect. This is referred to as a correspondence table.

The value of the evaluation index in the correspondence table can be arbitrarily determined, but it is desirable to conform to the data of the positive electrode potential and the temperature rise rate of the unit cell acquired in the past. Since values of the positive electrode potential and the temperature rise rate in the table are discrete, it is desirable to fill a blank using linear interpolation, for example. In the correspondence table, it is easy to reflect an event that may occur in the actual battery module, for example, variation in temperature change depending on the position. Formula can be obtained using the positive electrode potential and the temperature rise rate. However, information given to the evaluation index by other factors decreases to some extent.

Therefore, by using the correspondence table, it is possible to set the evaluation index in consideration of the influence in obtaining the evaluation index other than the positive electrode potential and the temperature rise rate. In addition, it is desirable that the ranges of the positive electrode potential and the temperature rise rate in the correspondence table include values that are considered to be taken by a unit cell. The vertical axis and the horizontal axis of the correspondence table can be interchanged. The evaluation index of one unit cell is derived by selecting the evaluation index at the time of taking the positive electrode potential and the temperature rise rate of one unit cell calculated in S2A and S2B with reference to the correspondence table. This operation is performed for all the unit cells in the battery module 2. By using the correspondence table, it is possible to set an evaluation index according to the design of the battery module 2.

In S5, the processing circuit 17 reads and executes the threshold comparison program 65 to compare the first evaluation index of the unit cell extracted in S4 with a first threshold A. For example, when the first evaluation index of the extracted unit cell is larger than the first threshold A (YES), the process proceeds to S6, and when the first evaluation index is equal to or smaller than the first threshold A (NO), the process proceeds to S10.

In S6, the processing circuit 17 reads and executes the second cell extraction program 66 to extract a unit cell (second unit cell) having the smallest first evaluation index from the result derived in S3. This is defined as a cell Y, and the first evaluation index of the cell Y is defined as S_{y}.

In S7, the processing circuit 17 reads and executes the second evaluation index derivation program 67 to derive the second evaluation index (Sₓ′) of the cell X when the cell X and the cell Y are swapped. The method for deriving the second evaluation index is similar to the method for deriving the first evaluation index of S3.

Table 2 shows various numerical values in a unit cell in the battery module 2 in deriving the second evaluation index.

In Table 2, similarly to Table 1, there are eight frames in the vertical direction i and three frames in the horizontal direction j, for a total of 24 frames. This table is regarded as a battery module, and each frame is regarded as a unit cell. In other words, eight unit cells are arranged in the vertical direction i and three unit cells are arranged in the horizontal direction j, and one battery module is formed by 24 unit cells. The values in each frame represent the positive electrode potential in (a) of Table 2, the temperature rise rate of the unit cell in (b) of Table 2, and the second evaluation index in the circled portion in (c) of Table 2, but the other numbers represent the first evaluation index. The number in the frame of (c) in Table 2 represents a value obtained by multiplying the obtained value by 100. In Table 2, a second evaluation index Sₓ′ in a case where, for example, a cell X with [i, j] of [3, 2] and a cell Y with [1, 3] are swapped is considered. Since the value of the positive electrode potential depends on the unit cell, the positive electrode potential v′₃₂ of [3, 2] is 4.28. Since the temperature rise rate depends on the position in the battery module, the temperature rise rate t; of [1, 3] which is the position of the cell Y is 0.50. When v′₃₂, t₁₃, and Cₜ=1.0 and Equations 1, 2, and 3 are used, the second evaluation index Sₓ′ can be calculated as 0.0264.

Extraction of a unit cell and derivation of the second evaluation index can also be performed for a plurality of unit cells. As described in the second embodiment, the extraction of the unit cell and the derivation of the second evaluation index can also be performed, for example, in all the unit cells other than the cell X.

In S8, the processing circuit 17 reads and executes the first replacement determination program 68 to compare the second evaluation index of the unit cell derived in S7 with a second threshold B. For example, when the second evaluation index of the extracted unit cell is smaller than the second threshold B (YES), the process proceeds to S9A, and when the second evaluation index is equal to or larger than the second threshold B (NO), the process proceeds to S9B. The first threshold A and the second threshold B can take different values, and the second threshold B can take a limited value than the first threshold A, for example, a value smaller than the first threshold A. The first threshold A and the second threshold B may be the same value. The first threshold A and the second threshold B can be changed in accordance with an environmental change such as an outside temperature.

In S9A, the processing circuit 17 can cause the user interface 20 to display a notification to swapping a unit cell with another unit cell in the battery module 2, for example, by reading and executing the notification program 69.

In S9B, by reading and executing the notification program 69, the processing circuit 17 can cause the user interface 20 to display a notification to replace a unit cell with, for example, a unit cell outside the battery module 2 or a new unit cell. In S9A and S9B, the user interface 20 having received the instruction outputs the notification of unit cell replacement or the like via the output device.

### Second Embodiment

As a modification of the first embodiment, a case where the target of the unit cell to be swapped with the cell X is all the unit cells other than the cell X will be described.

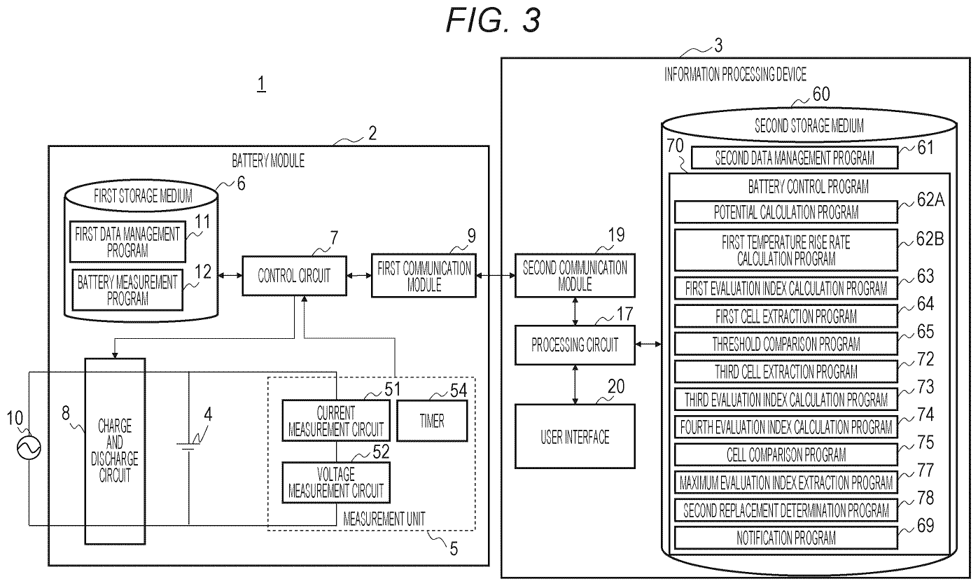

FIG. 3 is a block diagram illustrating a schematic modification of the battery system according to the embodiment. The first storage medium 6 includes a temperature measurement program for acquiring a temperature from a temperature sensor. The battery control program 70 includes a potential calculation program 62A, a first temperature rise rate calculation program 62B, a first evaluation index derivation program 63, a first cell extraction program 64, a threshold comparison program 65, a third cell extraction program 72, a third evaluation index derivation program 73, a fourth evaluation index derivation program 74, a cell comparison program 75, a maximum evaluation index extraction program 77, and a second replacement determination program 78.

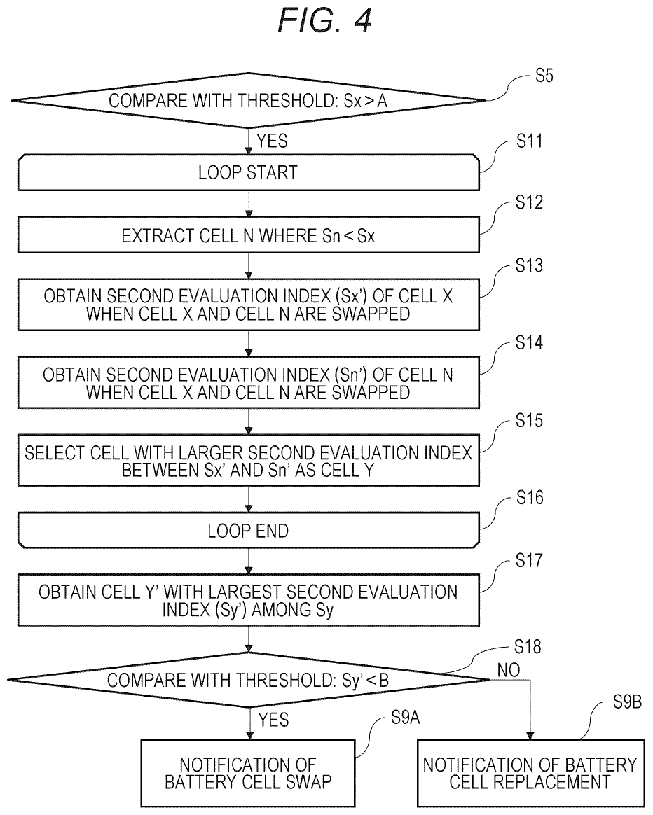

A flow of a battery diagnosis method according to a second embodiment will be described. FIG. 4 is an excerpt of a flowchart illustrating a modification of the flow of the battery system according to the embodiment. Steps S1 to S5 and steps S9A and S9B and subsequent steps are similar to those in FIG. 2, and thus description thereof is omitted. Here, S11 to S18 existing between S5 and S9A and S9B will be described.

In S11 and S16, the processing circuit 17 sets the range in which this loop is performed to S1l to S16, and ends when the loop is performed in all the unit cells other than the cell X in the battery module 2.

In S12, the processing circuit 17 reads and executes the third cell extraction program 72 to extract a unit cell having a first evaluation index smaller than the first evaluation index of the cell X from among all the unit cells derived in S3. The extracted unit cell is defined as a cell N, and the first evaluation index of the cell N is defined as Sₙ.

In S13, the processing circuit 17 reads and executes the third evaluation index derivation program 73 to derive the second evaluation index (Sₓ′) of the cell X when the cell X and the cell N are swapped.

In S14, the processing circuit 17 reads and executes the fourth evaluation index derivation program 74 to derive the second evaluation index (Sₙ′) of the cell N when the cell X and the cell N are swapped. The method for deriving Sₙ′ is similar to the method for deriving Sₓ′ in S13.

In S15, the processing circuit 17 reads and executes the cell comparison program 75 to compare the second evaluation index Sₓ′ of the cell X and the second evaluation index Sₙ′ of the cell N derived in S13 and S14. The unit cell having the larger second evaluation index is defined as a cell Y, and the second evaluation index of the cell Y is defined as S_{y}.

In S17, the processing circuit 17 reads and executes the maximum evaluation index extraction program 77 to extract a unit cell having the largest second evaluation index among the cells Y. This is referred to as a cell Y′, and the second evaluation index of the cell Y′ is referred to as S_{y}′.

In S18, the processing circuit 17 reads and executes the second replacement determination program 78 to compare the second evaluation index of the unit cell extracted in S17 with the second threshold B. For example, when the second evaluation index of the extracted unit cell is smaller than the second threshold B (YES), the process proceeds to S9A, and when the second evaluation index is equal to or larger than the second threshold B (NO), the process proceeds to S9B.

### Third Embodiment

As a modification of the first embodiment, a case where a temperature sensor is newly provided will be described.

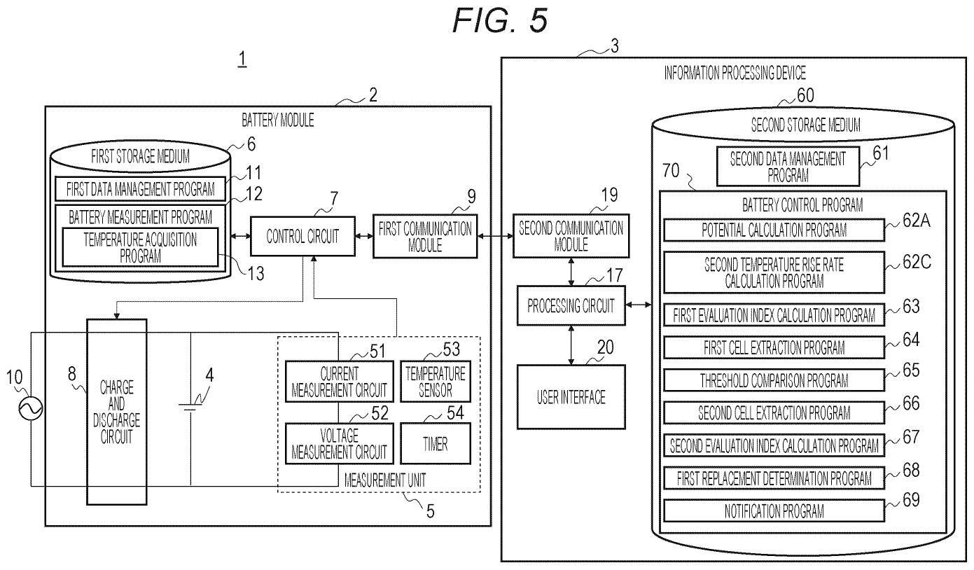

FIG. 5 is a block diagram illustrating a schematic modification of the battery system according to the embodiment. The measurement unit 5 includes a temperature sensor 53 in addition to the configuration of the measurement unit 5 in FIG. 1. The battery measurement program 12 in the first storage medium 6 includes a temperature acquisition program 13 for acquiring information on the temperature of the unit cell 4. The battery control program 70 includes a second temperature rise rate calculation program 62C instead of the first temperature rise rate calculation program 62B of the battery control program 70 of FIG. 1. The temperature acquisition program 13 may be included in the battery measurement program 12 on the battery module 2 side or may be included in the battery control program 70 on the information processing device 3 side.

For example, the temperature sensor 53 is directly attached to the unit cell 4 and acquires the temperature of the unit cell 4. In a case where information regarding the temperature can be directly acquired using the temperature sensor 53, the temperature distribution corresponds to the temperature rise rate.

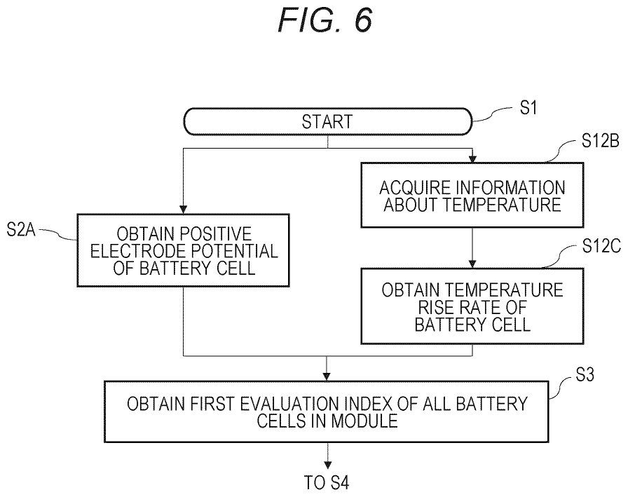

A flow of a battery diagnosis method according to a third embodiment will be described. FIG. 6 is an excerpt of a flowchart illustrating a modification of the flow of the battery system according to the embodiment. Steps S2A and S3 and subsequent steps are the same as those in FIG. 2, and thus description thereof is omitted. Here, S12B and S12C will be described.

In S12B, the control circuit 7 reads and executes the temperature acquisition program 13 to acquire information on the temperature in the unit cell 4 using the temperature sensor 53. The information regarding the temperature may be directly acquired using the temperature sensor 53, or may be acquired from a database or the like in which the information regarding the temperature is stored.

In S12C, the processing circuit 17 reads and executes the second temperature rise rate calculation program 62C to calculate the temperature rise rate of the unit cell 4. The temperature rise rate can be acquired, for example, by acquiring information on temperature at time T1, then similarly acquiring information on temperature at time T2 after time T1, and calculating a temperature change per elapsed time. The time interval between the time T1 and the time T2 is desirably 120 milliseconds or more, which is an interval that the temperature sensor 53 can sense. The temperature may be averaged to obtain more accurate information. For example, the temperature is acquired at time T1, and the temperature is acquired at time T1′ after time T1. The temperature of T1 and the temperature of T1′ are averaged, and the obtained value is taken as the temperature of T1. Next, the temperature is acquired at time T2 after time T1′, and the temperature is similarly acquired at time T2′ after time T2. The temperature of T2 and the temperature of T2′ are averaged, and the obtained value is taken as the temperature of T2. In this case, the elapsed time between T1′ and T2 is desirably longer than the elapsed time between T1 and T1′ or between T2 and T2′. As a result, it is possible to calculate a more accurate temperature rise rate with less influence of an error due to a temperature sensor or the like.

According to one or more embodiments and examples described above, there is provided an information processing device including a processing circuit that obtains a first evaluation index of a plurality of unit cells in a battery module and obtains a second evaluation index in a case where the first unit cell in the battery module and the second unit cell in the battery module are swapped on the basis of the first evaluation index, in which the first evaluation index and the second evaluation index are obtained on the basis of a positive electrode potential and a temperature rise rate. The information processing device according to the embodiment can provide an information processing device capable of achieving a long life of a battery module.

### Other Embodiments

In the present specification, the embodiment has been described using the lithium ion secondary battery as an example of a unit cell, but the type of the unit cell is not limited to a lithium ion secondary battery such as a nickel hydrogen battery. The battery module in each embodiment may be formed of three or more unit cells (unit cell batteries), or may be formed by electrically connecting a plurality of unit cells. When the battery module is formed of a plurality of unit cells, the plurality of unit cells may be electrically connected in series, or the plurality of unit cells may be electrically connected in parallel. In the secondary battery, both a series connection structure in which a plurality of unit cells are connected in series and a parallel connection structure in which a plurality of unit cells are connected in parallel may be formed. In addition, the battery module may be in the form of a battery string, a battery array, or the like in which a plurality of battery modules is electrically connected. In addition, in a battery module in which a plurality of unit cells are electrically connected, each of the plurality of unit cells may be individually controlled, or some of the plurality of unit cells may be grouped and controlled for each group.

In addition, the extraction of the unit cell having the largest first evaluation index may be performed by a plurality of unit cells. For example, a unit cell A having the largest first evaluation index and a unit cell B having the second largest first evaluation index are extracted. In this case, a unit cell C having the smallest first evaluation index and a unit cell D having the second smallest first evaluation index are extracted, and the second evaluation index of the unit cell A when the unit cell A and the unit cell C are swapped and the second evaluation index of the unit cell B when the unit cell B and the unit cell D are swapped may be calculated. Thus, the battery module can be operated more stably.

Although some embodiments of the present invention have been described, these embodiments have been presented as examples, and are not intended to limit the scope of the invention. These novel embodiments can be implemented in various other forms, and various omissions, substitutions, and changes can be made without departing from the gist of the invention. These embodiments and modifications thereof are included in the scope and gist of the invention, and are included in the invention described in the claims and the equivalent scope thereof.

Hereinafter, the invention of the embodiment will be additionally described.

<1>

An information processing device including a processing circuit configured to:
obtain a first evaluation index of a plurality of unit cells in a battery module; and
obtain a second evaluation index in a case where a first unit cell in the battery module and a second unit cell in the battery module are swapped on a basis of the first evaluation index,
in which the first evaluation index and the second evaluation index are obtained on a basis of a positive electrode potential and a temperature rise rate.

<2>

The information processing device according to <1>, further including
a processing circuit configured to
obtain the first evaluation index and the second evaluation index using a function based on a product or a weighted sum including values of the positive electrode potential and the temperature rise rate, or a correspondence table based on the positive electrode potential and the temperature rise rate.

<3>

The information processing device according to <1> or <2>, further including
a processing circuit configured to
obtain the second evaluation index by swapping a unit cell having a smallest first evaluation index and a unit cell having a largest first evaluation index in a case where the first evaluation index is equal to or less than a first threshold.

<4>

The information processing device according to any one of <1> to <3>, further including
a processing circuit configured to
give a notification of unit cell replacement in a case where the second evaluation index is equal to or less than a second threshold.

<5>

The information processing device according to any one of <1> to <4>, further including
a processing circuit configured to
calculate the positive electrode potential by analyzing a charge and discharge curve for each of the plurality of unit cells.

<6>

The information processing device according to any one of <1> to <5>, further including
a processing circuit configured to
calculate the temperature rise rate based on a distance from each of the plurality of unit cells to a surface of the battery module and a thermal conductivity in the battery module.

<7>

The information processing device according to any one of <1> to <6>, further including
a processing circuit configured to
calculate the temperature rise rate on the basis of information from a temperature sensor.

<8>

A battery system including:
the information processing device according to any one of <1> to <7>; and
a battery on which information processing is performed by the information processing device.

<9>

The battery system according to <8>, further including
a user interface capable of outputting information related to information processing of the battery and inputting information related to information processing of the battery.

<10>

A program for causing a processing circuit to perform operations of:
obtaining a first evaluation index of a plurality of unit cells in a battery module; and
obtaining a second evaluation index in a case where a first unit cell in the battery module and a second unit cell in the battery module are swapped based on the first evaluation index,
in which the first evaluation index and the second evaluation index are obtained based on a positive electrode potential and a temperature rise rate.

<11>

An information processing method including steps of:
obtaining a first evaluation index of a plurality of unit cells in a battery module; and
obtaining a second evaluation index in a case where a first unit cell in the battery module and a second unit cell in the battery module are swapped based on the first evaluation index,
in which the first evaluation index and the second evaluation index are obtained based on a positive electrode potential and a temperature rise rate.

What is claimed is:

1. An information processing device comprising a processing circuit configured to:
obtain a first evaluation index of a plurality of unit cells in a battery module; and
obtain a second evaluation index in a case where a first unit cell in the battery module and a second unit cell in the battery module are swapped on a basis of the first evaluation index,
wherein the first evaluation index and the second evaluation index are obtained on a basis of a positive electrode potential and a temperature rise rate.

2. The information processing device according to claim 1, further comprising
a processing circuit configured to
obtain the first evaluation index and the second evaluation index using a function based on a product or a weighted sum including values of the positive electrode potential and the temperature rise rate, or a correspondence table based on the positive electrode potential and the temperature rise rate.

3. The information processing device according to claim 1, further comprising
a processing circuit configured to
obtain the second evaluation index by swapping a unit cell having a smallest first evaluation index and a unit cell having a largest first evaluation index in a case where the first evaluation index is equal to or less than a first threshold.

4. The information processing device according to claim 1, further comprising
a processing circuit configured to
give a notification of replacement of the unit cell in a case where the second evaluation index is equal to or less than a second threshold.

5. The information processing device according to claim 1, further comprising
a processing circuit configured to
calculate the positive electrode potential by analyzing a charge and discharge curve for each of the plurality of unit cells.

6. The information processing device according to claim 1, further comprising
a processing circuit configured to
calculate the temperature rise rate based on a distance from each of the plurality of unit cells to a surface of the battery module and a thermal conductivity in the battery module.

7. The information processing device according to claim 1, further comprising
a processing circuit configured to
calculate the temperature rise rate on the basis of information from a temperature sensor.

8. A battery system comprising:
the information processing device according to claim 1; and
a battery on which information processing is performed by the information processing device.

9. The battery system according to claim 8, further comprising
a user interface capable of outputting information related to information processing of the battery and inputting information related to information processing of the battery.

10. A storage medium storing a program for causing a processing circuit to perform operations of:
obtaining a first evaluation index of a plurality of unit cells in a battery module; and
obtaining a second evaluation index in a case where a first unit cell in the battery module and a second unit cell in the battery module are swapped based on the first evaluation index,
wherein the first evaluation index and the second evaluation index are obtained based on a positive electrode potential and a temperature rise rate.

11. An information processing method comprising steps of:
obtaining a first evaluation index of a plurality of unit cells in a battery module; and
obtaining a second evaluation index in a case where a first unit cell in the battery module and a second unit cell in the battery module are swapped based on the first evaluation index,
wherein the first evaluation index and the second evaluation index are obtained based on a positive electrode potential and a temperature rise rate.
